(19) United States
(12) Patent Application Publication
(10) Pub. No.: US 2024/0429082 A1
(43) Pub. Date: Dec. 26, 2024

(54) FOUP HAVING END EFFECTOR DETECTION SENSOR, AND INTEGRATED DATA MANAGEMENT SYSTEM USING SAME

(71) Applicants: Kyu Ok LEE, Seongnam-si (KR); SAMSUNG ELECTRONICS CO., LTD., Suwon-si (KR)

(72) Inventors: Kyu Ok LEE, Seongnam-si (KR); Ji Yong KIM, Seongnam-si (KR)

(21) Appl. No.: 18/703,734

(22) PCT Filed: Oct. 5, 2022
(86) PCT No.: PCT/KR2022/014979

§ 371 Date: Apr. 23, 2024

(30) Foreign Application Priority Data
Dec. 21, 2021 (KR) 10-2021-0183641

(51) Int. Cl. H01L 21/677; H01L 21/67; H01L 21/68

(52) U.S. Cl. CPC H01L 21/67766; H01L 21/67259; H01L 21/681

(57) ABSTRACT

A FOUP comprises: an external server; and a substrate processing device for performing substrate processing and transmitting integrated management data to the external server. The substrate processing device comprises: FOUPs for accommodating a plurality of substrates; load ports to which the FOUPs are detachably coupled; a process chamber in which substrate processing is performed; an EFEM, which is provided between the process chamber and the load ports, and has an end effector for getting, into the process chamber, the substrates accommodated in the FOUPs or putting, into the FOUPs, the substrates for which processing is completed in the process chamber; and a control unit for transmitting, if the FOUPs are loaded in the load ports, moving path data of the end effector to the external server when the end effector enters into or retreats from the FOUPs.

### TECHNICAL FIELD

The present invention relates to a FOUP having an end effector detection sensor and an integrated data management system capable of managing various data related to substrate processing by using the same.

### BACKGROUND ART

Semiconductor manufacturing involves processing substrates through various equipment for photolithography, etching, deposition, polishing, and cleaning. During this process, the transfer of substrates between each piece of equipment is carried out by a FOUP (Front Opening Unified Pod), which is designed to stack multiple substrates (wafers) internally. Multiple substrates are loaded inside the FOUP, and it is either moved by an operator or transferred between the processing equipment using an automatic transfer system.

Once transferred, the FOUP is placed on the Equipment Front End Module (EFEM) of each processing equipment, where the EFEM opens the cover of the FOUP, exposing the substrates to the outside. Then, an atmospheric transfer robot's end effector within the EFEM retrieves one of the substrates loaded in the FOUP and transfers it to the processing chamber inside the processing equipment, and once processing is complete, places the substrate back inside the FOUP.

However, if the atmospheric transfer robot moves to the wrong location due to physical or control errors, the substrate can be damaged. To prevent this, substrate processing devices are equipped with a program that teaches the transfer path to the end effector of the atmospheric transfer robot to ensure it can accurately get or put substrates.

Nevertheless, since the atmospheric transfer robot is designed to move using spindles and several arms through chains or belts, there is a problem where the taught path may deviate if the belt loosens or the chain stretches.

To address this, Korean Patent No. 10-2020533, “End Effector Measurement Module and End Effector Monitoring Device Using the Same,” was disclosed.

However, the end effector monitoring device disclosed in the prior art has a problem in that the end effector measurement module is coupled to the supply port where substrates are supplied from the EFEM to the stage, making it difficult to install in existing substrate processing devices due to the limited installation space and interference with the workflow.

Furthermore, because the equipment and maintenance of the end effector measurement module are required, there is a problem that the substrate processing process must be halted since the processing chamber cannot be used during this process.

### DISCLOSURE

### Technical Problem

The objective of the present invention is to address the issues mentioned above by providing an integrated data management system for a substrate processing device. This system is equipped with means to detect the movement path of an end effector within a FOUP without interference with existing equipment, enabling the real-time detection and transmission of the end effector's movement path to a server.

Another objective of the present invention is to provide an integrated data management system for a substrate processing device that can verify whether the get and put operations by the end effector are accurately performed based on the detected movement path of the end effector.

A further objective of the present invention is to offer an integrated data management system for a substrate processing device that facilitates equipment management by integrating and transmitting both the movement path data of the end effector and the internal operational data of the equipment to a server during data transmission.

### Technical Solution

The objectives of the present invention can be achieved by a FOUP having an end effector detection sensor and an integrated data management system using the same. The integrated data management system of the substrate processing device according to the present invention includes an external server; and a substrate processing device that processes substrates and transmits integrated management data to the external server.

Here, the substrate processing device includes: a FOUP that accommodates multiple substrates; a load port to which the FOUP is detachably coupled; a processing chamber where the processing of substrates takes place; and an EFEM provided between the processing chamber and the load port, equipped with an end effector that gets substrates from the FOUP to the processing chamber or puts processed substrates from the processing chamber back into the FOUP.

Furthermore, when the FOUP is seated on the load port, it may include a control part that transmits the movement path data of the end effector to the external server when the end effector enters or retracts from the FOUP.

### Advantageous Effect

The integrated data management system according to the present invention is equipped with a detection means for sensing the transport path of the end effector inside the FOUP, offering the advantage of more convenient construction and maintenance. Additionally, there is an advantage in that the substrate processing operation does not need to be stopped even during the construction and maintenance of the detection means.

Furthermore, it is possible to determine whether the end effector is performing the get or put operation correctly by detecting the normal transport of the end effector, shifts, bending, and transport height.

Moreover, the control part communicates with the detection means inside the FOUP, receiving data on the transport path of the end effector, and also communicates with various sensor parts equipped inside the equipment to receive current equipment operation data. Then, it transmits the integrated management data, which combines the received transport path data and equipment operation data, to the external server in a batch, allowing the external server to quickly and accurately assess the current situation of the substrate processing device.

Additionally, if there is a difference in the normal condition of the get and put operations, the control part also transmits an anomaly signal to the external server, providing the advantage of allowing administrators to quickly respond to abnormal movements of the end effector.

### DESCRIPTION OF DRAWINGS

FIG. 1 is a schematic diagram showing the configuration of the integrated data management system according to the present invention,

FIG. 2 is a block diagram schematically showing the configuration of the integrated data management system according to the present invention,

FIG. 3 is a perspective view showing the configuration of the substrate processing device of the integrated data management system according to the present invention,

FIG. 4 is a plan view showing the planar configuration of the substrate processing device of the integrated data management system according to the present invention,

FIG. 5 is a perspective view showing the configuration of the FOUP of the integrated data management system according to the present invention,

FIG. 6 is an illustrative diagram showing the movement path detection means of the FOUP of the integrated data management system according to the present invention,

FIGS. 7 and 8 are illustrative diagrams showing the process of detecting the movement path of the end effector of the T-axis sensor of the FOUP of the integrated data management system according to the present invention,

FIG. 9 is an illustrative diagram showing the get operation of the end effector of the integrated data management system according to the present invention,

FIG. 10 is an illustrative diagram showing the put operation of the end effector of the integrated data management system according to the present invention,

FIG. 11 is an illustrative diagram showing the detected values during the get and put operations of the Z-axis sensor of the FOUP of the integrated data management system according to the present invention,

FIG. 12 is an illustrative diagram showing an example of the integrated management data transmitted to the external server in the integrated data management system according to the present invention.

### DESCRIPTION OF REFERENCE NUMERALS

1: Integrated Data Management System

10: Substrate Processing Device

20: External Server

100, 100a, 100b: Load Port

110: Adapter

200: EFEM

210: Atmospheric Transfer Robot

211: Rotating Arm

213: End Effector

213a: End Effector Arm

220: Transfer Robot Drive Part

221, 223: Spindle

230: Buffer Chamber Entrance

240: FOUP Entrance

300: Stage

310: Buffer Chamber

320: Conveying Robot

400: Processing Chamber

410: Chamber Entrance

420: Susceptor

500, 500a, 500b: FOUP

510: Housing

520: Substrate Mounting Rail

530: Entrance

540, 540a: T-axis Sensor

540: Light Emitting Sensor

540a: Light Receiving Sensor

550: Z-axis Sensor

560: Connector

570: Wireless Communication Part

600: Control Part

610: Internal Communication Part

620: Sensor Part

621, 623, 625: Pressure Sensor

627: Temperature Sensor

629: Concentration Sensor

W: Substrate

W′: Processed Substrate

### BEST MODE FOR INVENTION

The FOUP having an end effector detection sensor and the integrated data management system of the present invention include an external server 20; and a substrate processing device 10 that processes substrates and transmits integrated management data to the external server 20.

The substrate processing device 10 comprises a FOUPs 500, 500a, 500b that accommodates multiple substrates; a load ports 100, 100a, 100b to which the FOUPs 500, 500a, 500b is detachably coupled; a processing chamber 400 where processes on the substrate are carried out; and an Equipment Front-End Module (EFEM) 200 equipped with an end effector 213, situated between the processing chamber 400 and the load ports 100, 100a, 100b, which retrieves substrates accommodated in the FOUPs 500, 500a, 500b to the processing chamber 400 or places substrates processed in the processing chamber 400 back into the FOUPs 500, 500a, 500b. Additionally, it includes a control part 600 that transmits the movement path data of the end effector 213 to the external server 20 when the end effector 213 enters or retracts from the FOUPs 500, 500a, 500b upon the FOUPs 500, 500a, 500b being seated on the load ports 100, 100a, 100b.

### MODE FOR INVENTION

Hereinbelow, preferred embodiments of the present invention and the accompanying drawings are described in detail, with the premise that the same reference numerals in the drawings denote the same components.

When any one component is said to “include” another component in the detailed description of the invention or in the claims, unless specifically stated otherwise, it should not be interpreted as being limited to comprising only that component, but should be understood as possibly including other components.

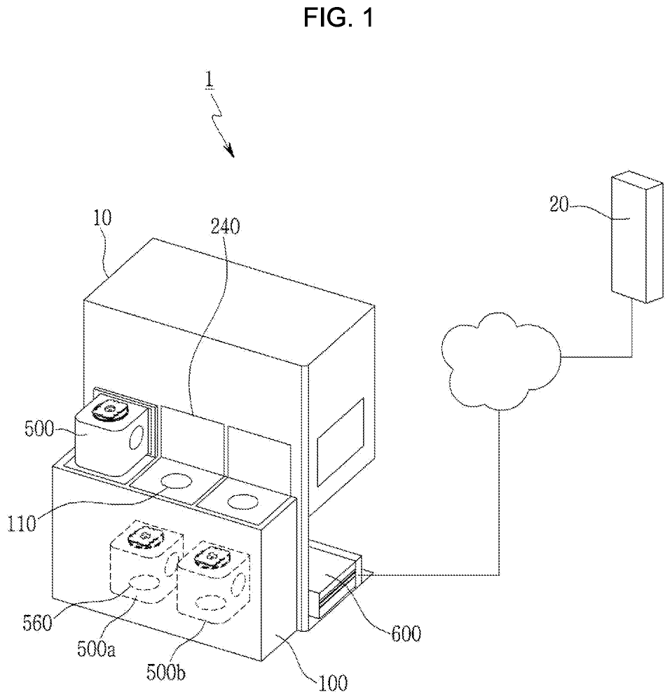

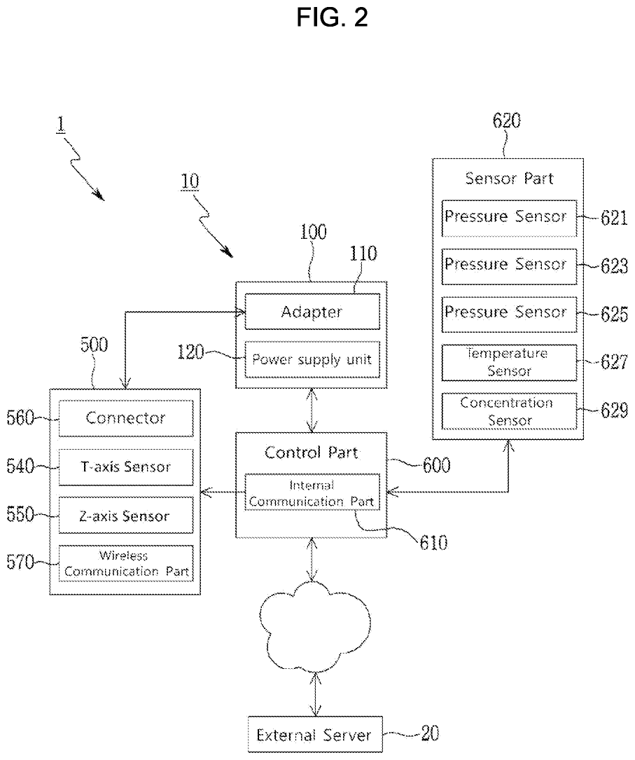

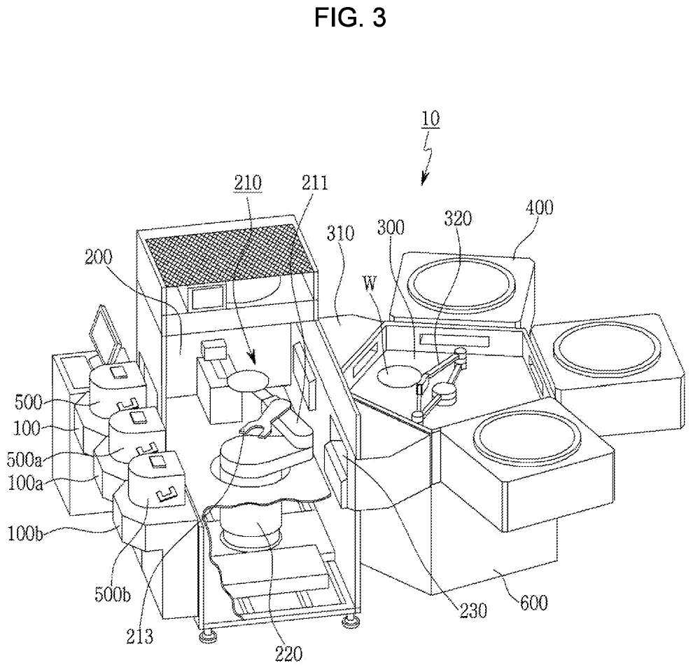

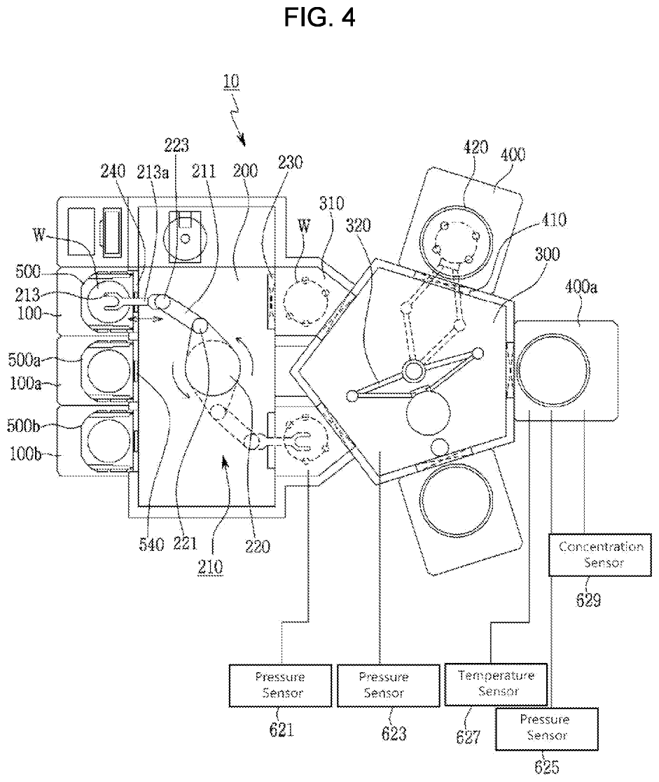

FIG. 1 is a schematic diagram showing the configuration of the Integrated Data Management System 1 for a substrate processing device according to the present invention, FIG. 2 is a block diagram schematically showing the internal configuration of the Integrated Data Management System 1 for the substrate processing device, FIG. 3 is a perspective view showing the configuration of the substrate processing device 10, and FIG. 4 is a plan view schematically showing the planar configuration of the substrate processing device 10.

As shown in FIGS. 1 and 2, the Integrated Data Management System 1 transmits integrated management data between the substrate processing device 10, where the processing of substrates is carried out, and an external server 20, ensuring that the current operational status within the substrate processing device 10 is accurately and swiftly conveyed to the external server 20.

Although only one substrate processing device 10 connected to an external server 20 is shown in FIGS. 1 and 2, multiple substrate processing devices 10, where different processes on substrates are carried out, are connected to the external server 20 via a communication network, transmitting integrated management data to the external server 20, which enables rapid understanding of the current substrate processing situation.

The substrate processing device 10 carries out various processes on substrates. It comprises a processing chamber 400 where processes on substrates W are conducted, a stage 300 supporting the processing chamber 400, an EFEM 200 coupled to the front end of the stage 300 and equipped with an end effector 213 that gets or puts substrates W onto the stage 300, load ports 100, 100a, 100b coupled to the EFEM 200, FOUPs 500, 500a, 500b in which substrates W are loaded and which are detachably seated on the load ports 100, 100a, 100b, and a control part 600 that controls these components, integrates data received from each component to generate integrated management data, and transmits the integrated management data to the external server 20.

The processing chamber 400 and stage 300 operate under vacuum pressure, while the load ports 100, 100a, 100b and the EFEM 200 operate under atmospheric pressure. The buffering chamber 310 of the stage 300 alternates between vacuum and atmospheric pressures.

The substrate processing device 10 according to the present invention is equipped with sensing means within the FOUPs 500, 500a, 500b, which are detachably coupled to the load ports 100, 100a, 100b, to detect the transfer path of the end effector 213. This allows for the quick determination of any misalignment during the get or put process of substrates W, preventing damage to the substrates W.

Furthermore, the sensing means provided in the FOUPs 500, 500a, 500b allow the control part 600 to determine whether the get or put operations of the end effector 213 are properly performed.

Additionally, equipment operation data received from various equipment detection sensors installed inside the substrate processing device 10, along with the end effector 213's movement path data detected by the sensing means, are transmitted to the external server 20 in the form of integrated management data. This allows the external server 20 to manage the substrate processing device 10 in a comprehensive and swift manner.

As shown in FIGS. 3 and 4, the load ports 100, 100a, 100b are coupled to the forefront of the EFEM 200, supporting the FOUPs 500, 500a, 500b. The load ports are provided in multiples, with each FOUPs 500, 500a, 500b mounted on the upper surface of each load port. Each of these load port surfaces is equipped with an adapter 110, which electrically couples with the FOUPs 500, 500a, 500b.

The adapter 110 electrically couples with the connector 560 located at the bottom of each FOUPs 500, 500a, 500b, allowing power to be supplied to the FOUPs by control of the control part 600.

The adapter 110 is equipped with an RFID (not shown in the drawings). The RFID identifies the FOUPs 500, 500a, 500b mounted on the adapter 110 and transmits the information of the respective FOUP to the external server 20.

The EFEM 200 transfers substrates W between the FOUPs 500, 500a, 500b mounted on the load ports 100, 100a, 100b, and the buffering chamber 310 of the stage 300. The EFEM 200 is equipped with an atmospheric transfer robot 210 that transfers substrates W and a transfer robot drive part 220 that drives the atmospheric transfer robot 210.

The atmospheric transfer robot 210 gets unprocessed substrates from inside the FOUPs and loads them into the buffering chamber 310, and unloads processed substrates from the processing chamber 400 back into the FOUPs. It includes a rotating arm 211 and an end effector 213 located at the end of the rotating arm 211 for transferring substrates W.

The transfer robot drive part 220 drives the atmospheric transfer robot 210 according to teaching values set by the control part 600, allowing the end effector 213 to sequentially get or put substrates. The transfer robot drive part 220 includes multiple spindles 221, 223 that rotate the rotating arm 211 and the end effector 213.

As shown in FIG. 4, depending on the rotation direction of the spindles 221, 223, the end effector 213 can be folded or unfolded from the rotating arm 211 and inserted into the FOUPs through the FOUP entrance 240, or inserted into the buffering chamber through the buffering chamber entrance 230.

The end effector 213 is designed to have substrates W loaded on its upper surface. It is formed in various shapes to accommodate the loading of substrates on its surface. Behind the end effector 213, there is an end effector arm 213a, which is a bar of a certain length.

The stage 300 supports multiple processing chambers 400 and is equipped with a buffering chamber 310 and a conveying robot 320, both connected to the EFEM 200. The stage 300 is formed in a polygonal shape, with multiple processing chambers 400 and a pair of buffering chambers 310 provided along each side of the polygon.

Each pair of buffering chambers 310 is loaded with unprocessed substrates and processed substrates, respectively, transferred by the end effector 213. The conveying robot 320 loads unprocessed substrates from the buffering chamber 310 into the processing chambers 400 or unloads processed substrates from the processing chambers 400 back into the buffering chambers 310.

The processing chambers 400 perform processing operations on substrates. Each processing chamber 400 is equipped with a susceptor 420 where substrates are loaded. The processing chambers 400 can be configured to perform various substrate processing operations. For example, it could be an ashing chamber designed to remove photoresist, a Chemical Vapor Deposition (CVD) chamber configured to deposit insulating films, an etch chamber designed to etch apertures or openings in insulating films to form interconnect structures, a Physical Vapor Deposition (PVD) chamber configured to deposit barrier layers, or a PVD chamber designed to deposit metal films.

As depicted in FIG. 4, the buffering chamber 310, stage 300, and processing chambers 400 are equipped with a sensor part 620 capable of detecting the current operational status of the equipment. The sensor part 620 may consist of multiple sensors such as pressure sensors 621, 623, 625, temperature sensor 627, and concentration sensor 629, which detect internal pressure, temperature, plasma gas concentration, and the number of substrates processed within the buffering chamber 310, stage 300, and processing chambers 400. Additionally, various other sensors capable of detecting the current operational status of the equipment may be provided. The sensor part 620 transmits the detected equipment conditions to the control part 600 in real-time.

The FOUPs 500, 500a, 500b accommodate multiple substrates internally and are detachably coupled between different substrate processing devices, allowing substrates to undergo different processes sequentially. Each FOUPs 500, 500a, 500b, as shown in FIG. 1, is mounted on the upper surface of the load ports 100, 100a, 100b.

The FOUPs 500, 500a, 500b of the present invention incorporate sensing means for detecting the entry and exit paths of the end effector 213. Furthermore, the FOUPs 500, 500a, 500b electrically connect to the adapter 110 of the load ports 100, 100a, 100b, transmitting the detected end effector 213's transfer path data to the control part 600.

The substrate processing device 10 of the present invention, by integrating the sensing means for detecting the transfer path of the end effector 213 within the FOUPs 500, 500a, 500b, offers advantages in ease of installation and maintenance compared to conventional setups where such sensing means were installed at the entrance of the stage's FOUP. Moreover, since the FOUPs 500, 500a, 500b are detachable, they offer the advantage of not having to halt the substrate processing device for the installation or maintenance of the sensing means.

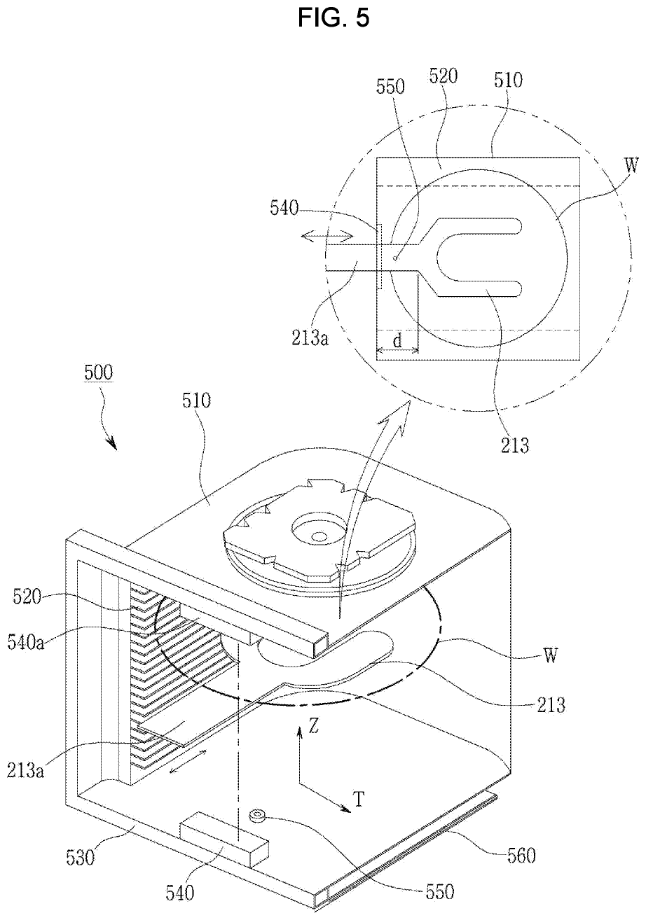

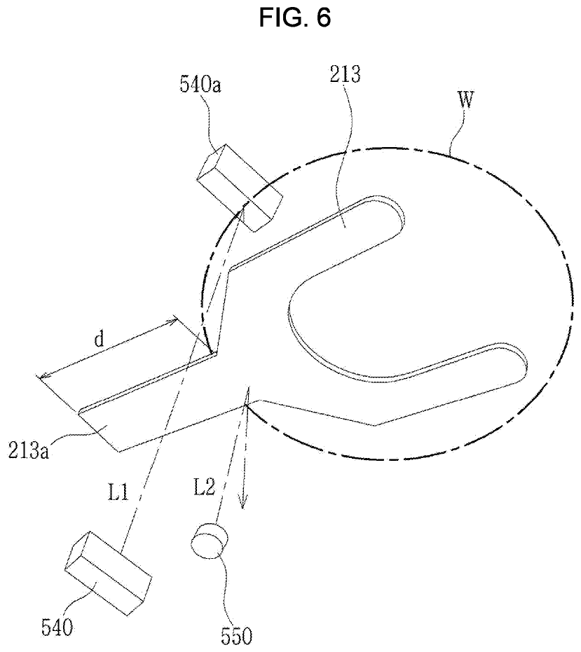

FIG. 5 is a perspective view showing the configuration of the FOUPs 500, 500a, 500b, and FIG. 6 is an illustrative diagram showing the process of detecting the transfer path of the end effector 213 within the FOUPs 500, 500a, 500b.

The FOUPs 500, 500a, 500b comprise a housing 510 in the form of a container, substrate mounting rails 520 formed at regular intervals along the height direction on both inner side walls of the housing 510 to mount substrates W, an entrance 530 arranged to correspond to the FOUP entrance 240 of the EFEM 200, T-axis sensors 540, 540a provided at the entrance 530 to detect the horizontal (T-axis) transfer path of the end effector 213, a Z-axis sensor 550 provided on the inner bottom surface of the entrance 530 to detect the vertical (Z-axis) transfer height of the end effector 213, a connector 560 provided on the bottom surface of the housing 510 to electrically couple with the adapter 110 of the load ports 100, 100a, 100b, and a wireless communication part 570 equipped inside the FOUPs 500, 500a, 500b to transmit the transfer data of the end effector 213 detected by the T-axis and Z-axis sensors to the control part 600.

When each of the FOUPs 500, 500a, 500b is mounted on the load ports 100, 100a, 100b, the connector 560 on the bottom surface of the housing 510 electrically connects with the adapter 110 of the load ports. Each connector 560 on the load ports is assigned a load port number from the external server 20.

When the wireless communication part 570 transmits the transfer data to the control part 600, the corresponding load port number is also transmitted, allowing the control part 600 and the external server 20 to identify the location of the load ports 100, 100a, 100b from which the data was sent.

The substrate mounting rails 520 are provided in multiples in a vertical direction on both walls, allowing multiple substrates to be arranged inside, spaced apart from each other.

A cap, not shown in the drawings, is coupled to entrance 530. When the FOUPs 500, 500a, 500b is connected to the load ports 100, 100a, 100b, the cap opens, allowing entrance 530 to communicate with the FOUP entrance 240, enabling the end effector 213 to enter or retract.

The end effector 213 moves according to the teaching information inputted through the external server 20. The T-axis sensors 540, 540a, and the Z-axis sensor 550 detect whether the end effector 213 transports the substrate to the correct position according to the teaching information and transmits this movement path data to the control part 600.

The T-axis sensors 540, 540a, located at entrance 530, detect the horizontal transfer path of the end effector 213 as it enters or exits the FOUPs 500, 500a, 500b. These sensors determine whether the end effector 213 is transferred horizontally to the correct position. More specifically, they detect whether the end effector 213 is shifted or twisted from the correct position during transfer.

The T-axis sensors 540, 540a are implemented as optical sensors that acquire information by illuminating light. They consist of a light-emitting sensor 540 located at the bottom of entrance 530, which illuminates light, and a light-receiving sensor 540a located at the top of entrance 530, corresponding to the position of the light-emitting sensor 540, to receive light.

The light-emitting sensor 540 is placed at the bottom of entrance 530 to prevent the illuminated light source from damaging the patterns formed on the surface of substrate W by ensuring the light is directed towards the backside of substrate W. The light-receiving sensor 540a receives the light emitted from the light-emitting sensor 540 and outputs variable output values as electrical signals to the control part 600 based on the amount of received light. The light-receiving sensor 540a can be implemented with photodiodes, PDS, etc.

Optical sensors are used as T-axis sensors 540, 540a because they are relatively free from ambient noise compared to other types of sensors, resulting in less measurement error and thus more accurate results. Additionally, their compact size makes them easier to install inside the space-constrained inspection FOUPs 500, 500a, 500b.

The information obtained by the T-axis sensors 540, 540a can include at least one of the following about the end effector 213: presence, transfer position, degree of twisting, and whether it has shifted. “Presence” means that if the light-receiving sensor 540a fully receives the light source without interference from the substrate or end effector 213, it is determined that neither the substrate nor end effector 213 exists in the light path. Conversely, if the light-receiving sensor 540a receives at least some of the light source with interference from the substrate or end effector 213, it is determined that either is present in the light path.

The “transfer position” and “degree of twisting or shifting” can be determined by the time the light is emitted by the light-emitting sensor 540 and the area of light received by the light-receiving sensor 540a.

Here, as shown in the drawings in FIG. 6, the T-axis sensors 540, 540a transmit the positional information of the entire end effector 213 and end effector arm 213a as they enter through entrance 530 to the control part 600. The control part 600 filters out only the area corresponding to the length (d) of the end effector arm 213a from the T-axis positional information received from the light-receiving sensor 540a to generate the transfer path data.

This is because if substrate W is loaded onto the end effector 213, the illumination would cause diffuse reflection; thus, only the data values corresponding to the area of the end effector arm 213a where diffuse reflection does not occur are extracted as transfer path data.

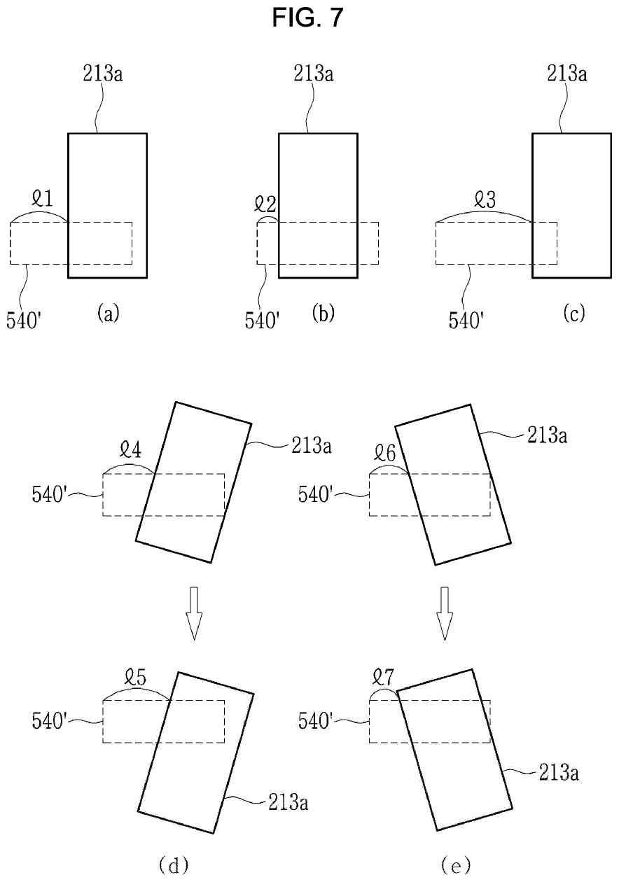

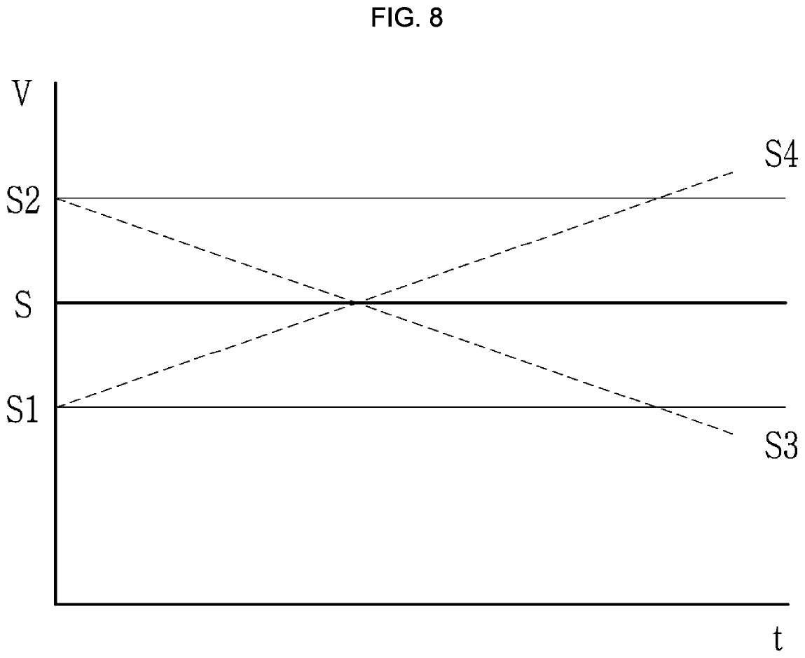

FIG. 7 illustrates various examples of the end effector arm 213a's path as detected by the T-axis sensors 540, 540a, and FIG. 8 shows an example of the electrical signal transmitted from the light-receiving sensor 540a to the control part 600.

FIG. 7(a) depicts the scenario where the end effector arm 213a moves along its normal path according to the teaching information. The end effector arm 213a moves in a direction orthogonal to the light-receiving sensor 540a, during which time a specific area, 50% of the area of the light-receiving sensor 540a, becomes obscured.

The condition where 50% of the light-receiving sensor 540a's area is obscured serves as a criterion to determine whether the end effector arm 213a is following its normal path. This allows for the identification of the direction in which the end effector arm 213a has shifted or tilted.

Therefore, when the end effector arm 213a passes through the entrance 530 of the FOUPs 500, 500a, 500b and covers 50% of the light-receiving sensor 540a's area, the output value (voltage) of the light-receiving sensor 540a remains constant at a reference value (S) as shown in FIG. 8.

FIG. 7(b) illustrates the scenario where the end effector arm 213a has shifted to the left of the light-receiving sensor 540a from its correct position as represented in the diagram, and FIG. 7(c) shows the scenario where the end effector arm 213a has shifted to the right of the light-receiving sensor 540a from its correct position.

In FIG. 7(b), when the end effector arm 213a shifts to the left of the light-receiving sensor 540a, the sensor is obscured more (l1>l2) compared to its correct position as shown in FIG. 7(a), resulting in the voltage output by the light-receiving sensor 540a dropping below the reference value (S), as indicated by S1 in FIG. 8.

Additionally, as shown in FIG. 7(c), when the end effector arm 213a shifts to the right of the light-receiving sensor 540a, the sensor becomes less obscured (11<13) compared to when the end effector arm 213a moves through its correct position, resulting in a higher output voltage from the light-receiving sensor 540a, as indicated in FIG. 8(S2), being above the reference value (S).

These changes in the voltage (or output) values of the light-receiving sensor 540a, while the end effector arm 213a moves in a linear direction, indicate that it has shifted either left or right from its normal position.

Additionally, FIGS. 7(d) and 7(e) illustrate examples of the end effector arm 213a tilting from its normal position. FIG. 7(d) shows the end effector arm 213a tilting to the right as it moves into the FOUPs 500, 500a, 500b, and FIG. 7(e) shows it tilting to the left.

As depicted in FIG. 7(d), when the end effector arm 213a tilts and moves to the right, the area obscured by the light-receiving sensor 540a increases (l4<l5) as the end effector arm 213a progresses into the interior of the FOUPs 500, 500a, 500b over time. Consequently, the voltage output from the light-receiving sensor 540a forms a graph that transitions from a high to a low value over time, as illustrated in S3 of FIG. 8.

Similarly, as shown in FIG. 7(e), when the end effector arm 213a tilts and moves to the left from its normal position, the area obscured by the light-receiving sensor 540a increases (l6>l7) as the end effector arm 213a enters the FOUPs 500, 500a, 500b over time. If the setting is such that a larger obscured area results in a higher voltage output, the voltage output from the light-receiving sensor 540a forms a graph transitioning from a low to a high value, as shown in S4 of FIG. 8.

The Z-axis sensor 550 detects the vertical movement height (Z-axis direction) of the end effector arm 213a as it enters the interior of the FOUPs 500, 500a, 500b. Positioned on the inner bottom of entrance 530, the Z-axis sensor 550 can be implemented as a laser sensor that emits light towards the end effector 213. By measuring the time it takes for the light reflected from the end effector 213 to be received, the sensor determines the height of the end effector arm 213a, as illustrated in FIG. 6.

If the light reflection time remains constant as the end effector arm 213a enters, it is inferred that the arm is moving horizontally. However, if there's a change in the light reflection time during the entry, it indicates that the end effector arm 213a is either tilting or entering in an incorrect position.

The connector 560, mounted on the adapter 110 of the load ports 100, 100a, 100b, receives power. The power supplied through the adapter 110 is distributed to the T-axis sensors 540, 540a, the Z-axis sensor 550, and the wireless communication part 570.

When the FOUPs 500, 500a, 500b is mounted on the EFEM 200, the wireless communication part 570 engages in wireless communication with the internal communication part 610 of the control part 600. It transmits real-time transfer path data of the end effector 213, detected by the Z-axis sensor 550 and T-axis sensors 540, 540a, to the control part 600.

The control part 600 manages the components such that when the FOUPs 500, 500a, 500b is mounted on the load ports 100, 100a, 100b, the unprocessed substrates are transferred to the processing chamber 400 for processing, and the processed substrates are then transferred back to the FOUPs 500, 500a, 500b.

Additionally, when the FOUPs 500, 500a, 500b is mounted on the load ports 100, 100a, 100b, the control part 600 ensures that power from the power supply unit 120 is supplied to the FOUPs 500, 500a, 500b through the adapter 110.

An RFID tag (not shown in the drawings) integrated into the adapter 110, transmits the product information of the mounted FOUPs 500, 500a, 500b to the external server 20. The external server 20, upon receiving the FOUP's product information, executes the corresponding teaching information to the transfer robot drive part 220, enabling its operation.

As a result, the end effector 213 moves towards the FOUPs 500, 500a, 500b and transfers the substrate W to the buffering chamber 310. During this process, the T-axis sensors 540, 540a, and the Z-axis sensor 550 transmit the real-time transfer path data of the end effector 213 and the end effector arm 213a to the control part 600 via the wireless communication part 570.

The control part 600, through the internal communication part 610, extracts data corresponding to the length (d) of the end effector arm 213a from the total transfer path data transmitted by the T-axis sensors 540, 540a, and the Z-axis sensor 550 of the FOUPs 500, 500a, 500b, to create the transfer path data.

This generated transfer path data is then compared with the taught normal path to determine whether the end effector 213 is correctly performing the put or get operations on substrate W along the normal path.

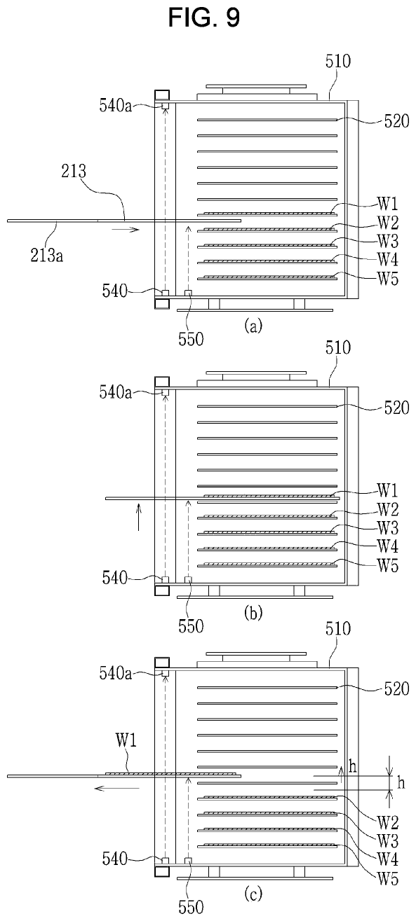

FIG. 9 illustrates the process of the end effector 213 getting an unprocessed substrate W from the FOUPs 500, 500a, 500b. As shown in FIG. 9(a), the end effector 213 inserts through entrance 530 into the interior of the FOUPs 500, 500a, 500b.

The end effector 213 moves according to the teaching path received from the external server 20 and sequentially gets substrates, starting from the one loaded on the uppermost substrate mounting rail 520 down to the lower ones, and transfers them to the buffering chamber 310.

During this time, the light-emitting sensor 540 illuminates light, and the light-receiving sensor 540a receives the light, transmitting the real-time transfer path data of the end effector 213 to the control part 600.

The end effector 213 enters between the substrate mounting rail 520 holding the topmost substrate W1 and the next substrate W2 below it. As depicted in FIG. 9(b), it rises a certain height (h) upward and mounts the substrate W1 on its surface. After mounting substrate W1, the end effector 213 retracts outside the FOUPs 500, 500a, 500b.

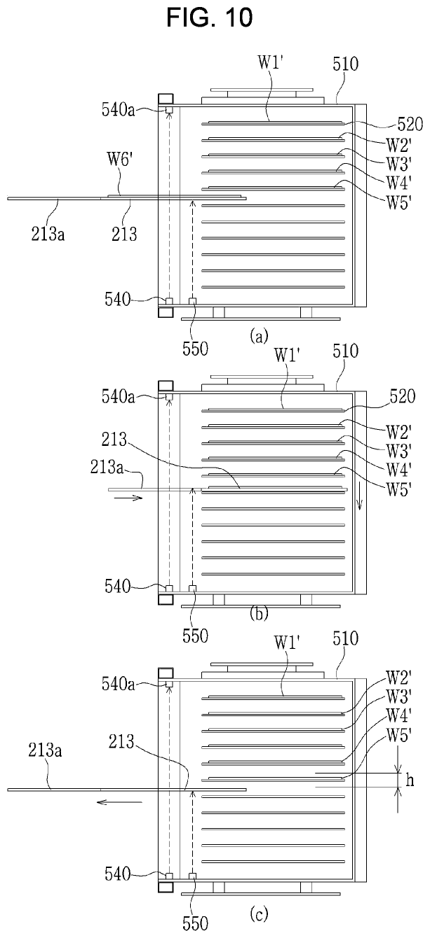

FIG. 10 illustrates the process of the end effector 213 putting a processed substrate back into the FOUPs 500, 500a, 500b. After unloading the processed substrate W6′ from the buffering chamber 310, the end effector 213 enters the FOUPs 500, 500a, 500b as shown in FIG. 10(a). The processed substrate W6′ is placed below the pre-loaded pre-processed substrate W5′.

To achieve this, the end effector 213 inserts below the substrate mounting rail 520 holding the pre-processed substrate W5′ and descends to a certain height (h) as depicted in FIG. 10(b), placing the processed substrate W6′ onto the substrate mounting rail 520.

Subsequently, as shown in FIG. 10(c), the end effector 213 retracts outside the FOUPs 500, 500a, 500b.

During the get and put operations performed by the end effector 213, the Z-axis sensor 550 and T-axis sensors 540, 540a transmit the complete movement path data of the end effector arm 213a to the control part 600 via the wireless communication part 570.

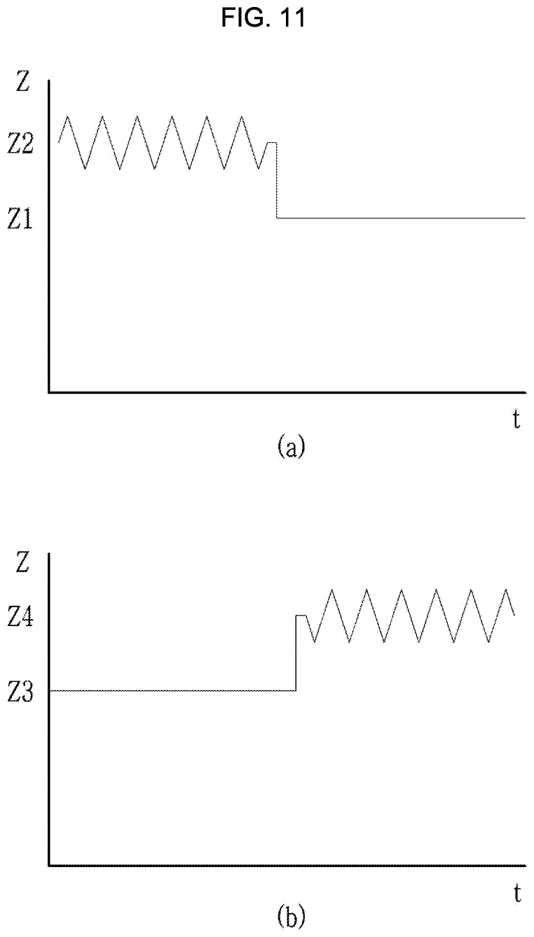

FIG. 11(a) exemplifies the Z-axis values transmitted from the Z-axis sensor 550 to the control part 600 during a put operation. If the Z-axis sensor 550 is configured to increase the voltage value with height, as the end effector 213 enters the FOUPs 500, 500a, 500b with a processed substrate W loaded, the light reflected off the substrate W results in irregular height values (Z2) being received by the Z-axis sensor 550. Once the substrate W is mounted onto the substrate mounting rail 520, a decreased height value (Z1), lower by a certain height (h) than the entry height (Z2), is received.

FIG. 11(b) shows the height values transmitted from the Z-axis sensor 550 to the control part 600 during a get operation. As depicted, the end effector 213 enters without a substrate, resulting in a consistent height value at the initial third height (Z3). When the substrate W is gotten, a reflected irregular height value at the fourth height (Z4), which is higher by a certain height (h), is received.

The control part 600 can determine whether the put and get operations are performed correctly based on the movement path data of the end effector arm 213a received from the T-axis sensors 540, 540a, and the Z-axis sensor 550.

Furthermore, the control part 600 sends integrated management data, which includes both the movement path data from the end effector arm 213a transmitted by the T-axis sensors 540, 540a, and the Z-axis sensor 550, and the current operation data from the equipment sent by the sensor part 620, to the external server 20.

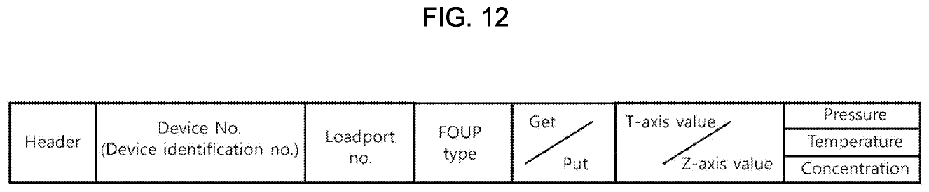

FIG. 12 illustrates an example of integrated management data. This data comprises a header, equipment number, load port number, FOUP type, indicators of whether a get or put operation has occurred, movement path data (T-axis and Z-axis values), and operation data (pressure, temperature, concentration, etc.). This comprehensive data set enables detailed monitoring and management of the substrate processing operations.

The equipment number and load port number are unique identifiers assigned to each substrate processing device 10.

The external server 20 is connected to various types of substrate processing devices 10 via the internet or similar networks, receiving integrated management data from the control part 600 of each substrate processing device. This setup allows for a collective and comprehensive report on the current substrate processing operations of each substrate processing device 10.

As a result, the data is not reported separately but is batch-received by the external server 20 from the control part 600 through integrated management data. This approach significantly reduces the time required to manage multiple substrate processing devices 10.

During this process, if the control part 600 detects any deviation in the current transfer path of the end effector arm 213a from the normal path, based on data received from the T-axis sensors 540, 540a, and the Z-axis sensor 550, it sends an alert signal along with the deviation data to the external server 20. This enables the administrator managing the external server 20 to immediately become aware of any anomalies.

Consequently, this system can prevent or minimize substrate damage caused by abnormal movements of the end effector 213, ensuring the reliability and efficiency of the substrate processing operations.

The integrated data management system of the present invention is designed to receive power from a power supply unit 120 when the FOUPs 500, 500a, 500b are mounted on the adapter 110 of the load ports 100, 100a, 100b. However, depending on the circumstances, the adapter and power supply unit can be integrated into a wireless charging unit.

This innovation provides the advantage of making the installation and maintenance more convenient, as it equips the FOUPs with sensing means to detect the transfer path of the end effector within. Moreover, it offers the benefit of not having to halt the substrate processing operations during the installation or maintenance of the sensing means.

Additionally, the system can detect the normalcy of the end effector's transfer, any shifts, bends, and the transfer height, thereby determining whether the end effector is correctly performing the get or put operations.

The control part communicates with the sensing means inside the FOUP to receive data on the end effector's transfer path and communicates with various sensors within the equipment to receive current operation data of the equipment. This received transfer path data and equipment operation data are then combined into integrated management data and sent to the external server in a batch, allowing the external server to quickly and accurately assess the current status of the substrate processing device.

Furthermore, if there is any deviation in the get or put operations from the normal state, the control part sends an alert signal along with the deviation data to the external server. This feature allows the manager to quickly address any abnormal movements of the end effector, highlighting the system's capability to promptly respond to and mitigate potential issues, thus ensuring the reliability and efficiency of the substrate processing operations.

Through various embodiments, we have explored the technical spirit of the present invention. It is evident that those skilled in the art to which the present invention pertains could readily modify or change the embodiments reviewed here without departing from the scope of the invention, based on the disclosure herein. Moreover, it is apparent that various forms of modifications that include the technical spirit of the invention, even if not explicitly illustrated or described, are possible by those skilled in the art and still fall within the scope of the invention. The embodiments described with reference to the accompanying drawings are for illustrative purposes only and are not intended to limit the scope of the invention.

### INDUSTRIAL APPLICABILITY

The FOUP with end effector detection sensors and the integrated data management system in accordance with the present invention can be employed in semiconductor equipment, facilitating integrated management of semiconductor equipment.

1. An Integrated data management system for a substrate processing device, comprising:
An external server; and
A substrate processing device where substrate processing is conducted and which transmits integrated management data to the external server,
wherein the substrate processing device includes:
FOUPs accommodating multiple substrates;
Load ports to which the FOUPs are detachably coupled;
A processing chamber where the processing of substrates is conducted;
An Equipment Front-End Module (EFEM) provided between the processing chamber and the load ports, equipped with an end effector that gets substrates from the FOUPs to the processing chamber or puts processed substrates from the processing chamber back into the FOUPs; and
A control part that, when the FOUPs are seated on the load ports, transmits the movement path data of the end effector as it enters or exits the FOUPs to the external server.

2. The integrated data management system for a substrate processing device according to claim 1,
wherein the FOUP includes:
A housing with an entrance for the entry and exit of the end effector;
Substrate mounting rails on both sides of the housing, spaced at regular intervals vertically, for sequentially loading multiple substrates;
T-axis sensors provided above and below the entrance to detect the horizontal movement path of the end effector;
A Z-axis sensor located at the inner bottom of the entrance to detect the vertical movement height of the end effector as it moves through the entrance;
A connector at the bottom of the housing for electrical coupling with the load ports; and
A wireless communication part inside the housing to transmit the detection values from the T-axis sensors and the Z-axis sensor to the control part.

3. The integrated data management system for a substrate processing device according to claim 2, wherein:
The T-axis sensors consist of a light-emitting sensor positioned at the bottom of the housing and a light-receiving sensor placed at the top of the housing, opposite the light-emitting sensor, to detect shifts and tilts in the T-axis direction based on the received light amount; and
The Z-axis sensor is a laser sensor that emits light from the bottom of the housing towards the end effector and detects the movement height of the end effector based on the time it takes for the reflected light from the end effector to be received.

4. The integrated data management system for a substrate processing device according to claim 3, wherein the load ports are equipped with adapters corresponding to the connectors, and the control part, upon electrical connection of the connector to the adapter, supplies power to the FOUP, receives the movement path data of the end effector detected by the T-axis sensors and the Z-axis sensor from the wireless communication part, and transmits this movement path data to the external server.

5. The integrated data management system for a substrate processing device according to claim 4, wherein a linear-shaped end effector arm is provided at the rear of the end effector, and the control part determines the movement path of the end effector based on the T-axis and Z-axis values of the end effector arm, and uses the Z-axis values transmitted from the Z-axis sensor to determine whether the operation is a put or a get action and to judge if the operation was performed correctly.

6. The integrated data management system for a substrate processing device according to claim 5, wherein the EFEM and the processing chamber are equipped with a sensor part that detects current equipment operation information, and the control part transmits integrated management data, which includes both the movement path data and the equipment operation data measured by the sensor part, to the external server.
